(19) United States
(12) Patent Application Publication
(10) Pub. No.: US 2007/0138009 A1
(43) Pub. Date: Jun. 21, 2007

(54) Sputtering apparatus

(75) Inventors: Jin Seok Lee, Gyeongsangbuk-do (KR); Hyuk Sang Yoon, Busan-si (KR); Hwan Kyu Yoo, Gyeonggi-do (KR); Byeong Eok Hwang, Gyeongsangbuk-do (KR)

Correspondence Address: SEYFARTH SHAW, LLP, 815 CONNECTICUT AVENUE, N.W., SUITE 500, WASHINGTON, DC, 20006, US

(73) Assignees: LG.PHILIPS LCD CO., LTD., Seoul (KR); AVACO CO., Ltd., Daegu-si (KR); LG Electronics Inc., Seoul (KR)

(21) Appl. No.: 11/639,223

(22) Filed: Dec. 15, 2006

(30) Foreign Application Priority Data
Dec. 16, 2005 (KR) 10-2005-0124312

(51) Int. Cl. C23C 14/00

(52) U.S. Cl. 204/298.16

(57) ABSTRACT

A sputtering apparatus includes a cathode for generating a plasma; one or more target on a front surface of the cathode; a plurality of magnets at a first distance from a back of the cathode for generating a first magnetic field intensity in the plasma; and a plurality of guide members for moving the individual magnets in a direction substantially perpendicular to the cathode to a second distance from the back of the cathode to change the first magnetic field intensity to a second magnetic field intensity.

This application claims the benefit of Korean Patent Application No. 2005-0124312, filed on Dec. 16, 2005, which is hereby incorporated by reference in its entirety.

### BACKGROUND OF THE INVENTION

1. Field of the Invention

Embodiments of the present invention relate to a processing apparatus, and more particularly, to a sputtering apparatus for an LCD device. Embodiments of the present invention are suitable for a wide scope of applications. In particular, embodiments of the present invention are suitable for providing a sputtering apparatus capable of performing one or more process.

2. Description of the Related Art

Generally, semiconductor devices and display panels, such as liquid crystal display devices and organic light emitting display devices, are fabricated in a processing apparatus. The processing apparatus performs repeated manufacturing processes required for fabricating a wafer for a semiconductor device or a substrate for a display panel. The processing apparatus automates various processes by using robots. This automation of the fabrication process allows mass production of larger panel sizes using more complex processes.

Processing apparatuses for semiconductor and LCD devices are classified into a cluster type and an in-line type. A cluster type processing apparatus conveys a substrate horizontally between each chamber. In contrast, an in-line processing apparatus conveys a substrate vertically between each chamber.

Contamination by impurities such as particles may be reduced in the cluster type process apparatus because the substrate is transferred horizontally by a robot. However, the size of the chambers in the cluster-type processing apparatus must correspond to the size of the horizontally-placed substrate. Specifically, the size of each chamber increases with the size of the substrate. Accordingly, the size of components and the volume of the chamber in the cluster-type processing apparatus increases, thereby increasing the manufacturing cost. Hence, cost-effectiveness may be reduced. These problems can be avoided by using an in-line processing apparatus.

FIG. 1 is a perspective view of an in-line processing apparatus in accordance with the related art. Referring to FIG. 1, the related art in-line processing apparatus includes five units. For example, the related art in-line processing apparatus includes a conveying unit 121, a loading chamber 122, a buffer chamber 123, a process chamber 124, and a rotation chamber 125.

The in-line processing apparatus transfers a substrate between chambers 121 to 125 in a substantially vertical manner. The substrates are transferred from the conveying unit 121 to the rotary chamber 125 through the loading chamber 122, the buffer chamber 123 and the process chamber 124 in sequential order. Fabrication processes, such as a layer or film formation process and an etch process, are performed over the substrates in the process chamber 124. The rotation chamber 125 rotates the substrate to be transferred back to the process chamber 124, the buffer chamber 123, the loading chamber 122, and the conveying unit 121. Then, the rotated substrate is sequentially transferred through the process chamber 124, the buffer chamber 123, the loading chamber 122, and the conveying unit 121. Then, the substrate is transferred out of the conveying unit 121 to a sending unit.

Depending on a fabrication process, the process chamber 124 may be a sputtering chamber, an etching chamber, or an annealing chamber. In the sputtering chamber, a material is deposited over the substrates. In the etching chamber, a material is etched over portions of the substrates. In the annealing chamber, a material over portions of the substrates is annealed to stabilize properties of the material. Hereinafter, a sputtering chamber will be used as the process chamber 124. So, the process chamber 124 will be referred to as the sputtering chamber and the processing apparatus as a sputtering apparatus.

A gate valve (not shown) is disposed between each of the chambers 121 to 125 for opening and closing during substrate transfer. As described above, the in-line processing apparatus substantially vertically transfers the substrate that is attached to a carrier.

FIG. 2 is a cross-sectional view of a sputtering chamber in the related art in-line processing apparatus of FIG. 1. Referring to FIG. 2, a target 131, a cathode 132 and a first magnet 133 are arranged on one side of the related art in-line type sputtering apparatus. A sheath heater 135 is arranged on an another side of the in-line sputtering apparatus to face the cathode 132. A substrate 140 is loaded over a carrier 138 and transferred while standing up right in a vertical direction. A second magnet 139 having a certain polarity is placed on top of the carrier 138. A third magnet 136 having an opposite polarity to the second magnet 139 is placed above the second magnet 139, such that the third magnet 136 is spaced apart from and facing the second magnet 139. A metal belt 137 is mounted on the bottom of the carrier 138 to transfer the substrate 140. The metal belt 137 may be formed of a stainless steel material. For example, the material for the metal belt 137 may be an SUS stainless steel. The carrier 138 may be formed of an aluminum material. A vacuum pump 141 discharges air to provide a high pressure in the sputtering apparatus.

In the related art sputtering apparatus, the carrier 138 is kept in an up-right position by an attraction force between the second magnet 139 and the third magnet 136. A voltage is applied to the cathode 132 to ionize a gas in the sputtering chamber 124. Hence, a gaseous plasma is generated in the sputtering chamber 124. Positive ions in the gaseous plasma collide with the target 131 to cause a target material to be discharged from the target 131. The target material is deposited over the substrate 140. After the deposition of the target material on the substrate 140, the substrate 140 can be transferred to the next processing stage by the metal belt 137.

The first magnet 133 spaced apart from the cathode 132 imparts a uniform density to the plasma generated on the front surface of the cathode 132. The uniform density is produced by a horizontal lengthwise motion of the first magnet 133.

In the related art sputtering apparatus, process conditions, such as magnetic field intensities, differ depending on the types of materials to be deposited. For example, deposition of a metal material in the sputtering apparatus may require a magnetic field with a maximum intensity of about 200 gauss (G). Deposition of an indium tin oxide (ITO) material may require a magnetic field with a maximum intensity of about 900 G.

However, the magnetic field intensity of the first magnet 133 installed in the related art sputtering apparatus is optimized for depositing a specific material. Hence, the use of the related art sputtering apparatus may be limited to depositing the specific material. Accordingly, the related art sputtering apparatus often may not be used to deposit other materials. For this reason, the use of the sputtering apparatus may be restricted.

Accordingly, a different related art sputtering apparatus may be required for depositing each different material. Moreover, installation of the required multiple sputtering apparatuses increases space requirement. Thus, manufacturing cost is increased by the need to purchase different sputtering apparatuses. Hence, cost-effectiveness may be reduced.

### SUMMARY OF THE INVENTION

Accordingly, embodiments of the present invention are directed to a sputtering apparatus that substantially obviates one or more problems due to limitations and disadvantages of the related art.

An object of the present invention is to provide a sputtering apparatus that reduces manufacturing cost.

Another object of the present invention is to provide a sputtering apparatus that reduces a space requirement.

Additional features and advantages of the invention will be set forth in the description of exemplary embodiments which follows, and in part will be apparent from the description of the exemplary embodiments, or may be learned by practice of the exemplary embodiments of the invention. These and other advantages of the invention will be realized and attained by the structure particularly pointed out in the written description of the exemplary embodiments and claims hereof as well as the appended drawings.

To achieve these and other advantages and in accordance with the purpose of the present invention, as embodied and broadly described, a sputtering apparatus includes a cathode for generating a plasma; one or more target on a front surface of the cathode; a plurality of magnets at a first distance from a back of the cathode for generating a first magnetic field intensity in the plasma; and a plurality of guide members for moving the individual magnets in a direction substantially perpendicular to the cathode to a second distance from the back of the cathode to change the first magnetic field intensity to a second magnetic field intensity.

In another aspect, a sputtering apparatus includes a maintaining part for holding a substrate; and a sputtering part. The sputtering part includes a cathode for generating a plasma; one or more target on a front surface of the cathode; a plurality of magnets at a first distance from a back of the cathode for generating a first magnetic field intensity in the plasma; and a plurality of guide members for moving the individual magnets in a direction substantially perpendicular to the cathode to a second distance from the back of the cathode to change the first magnetic field intensity to a second magnetic field intensity.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of embodiments of the present invention and are incorporated in and constitute a part of this application, illustrate embodiments of the present invention and together with the description serve to explain the principle of embodiments of the present invention. In the drawings:

FIG. 1 is a perspective view of an in-line processing apparatus in accordance with the related art;

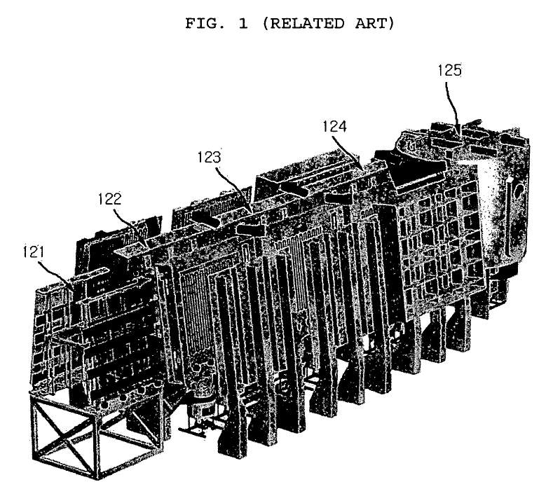

FIG. 2 is a cross-sectional view of a sputtering chamber in the related art in-line processing apparatus of FIG. 1;

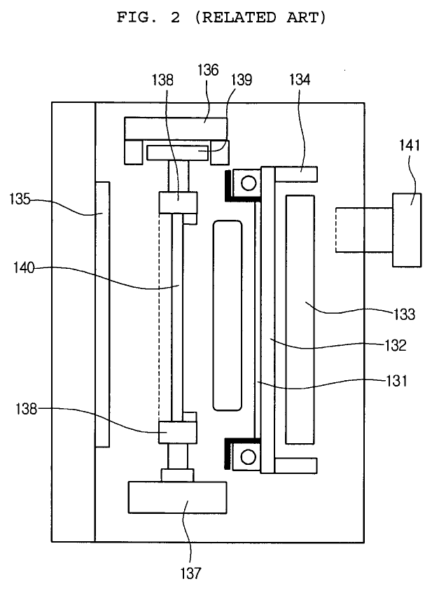

FIG. 3 is a cross-sectional view of an exemplary in-line type sputtering apparatus according to a first embodiment of the present invention;

FIGS. 4A and 4B are schematic diagrams illustrating exemplary control of the magnetic field intensity in the in-line sputtering apparatus illustrated in FIG. 3; and

FIG. 5 is a cross-sectional view of an exemplary cluster type sputtering apparatus according to an embodiment of the present invention.

### DETAILED DESCRIPTION OF THE INVENTION

Reference will now be made in detail to the preferred embodiments of the present invention, examples of which are illustrated in the accompanying drawings.

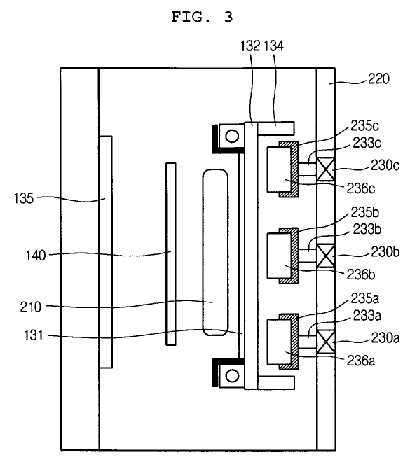

FIG. 3 is a cross-sectional view of an exemplary in-line type sputtering apparatus according to a first embodiment of the present invention. Referring to FIG. 3, the in-line sputtering apparatus includes a cathode 132 on one side thereof and a sheath heater 135 on the other side thereof. A substrate 140 is transferred into the in-line sputtering apparatus in an upright stance, for example in a substantially vertical direction. The substrate 140 is placed between the cathode 132 and the sheath heater 135. The substrate 140 may be transferred and kept in its upright position using on an air pad (not shown) or a carrier (not shown).

In an embodiment, an air pad is used to provide an air cushion to maintain the substrate 140 in the upright position while being transferred in the in-line sputtering apparatus. The air pad injects a gas material, such as Ar gas, toward the surface of the substrate 140 to generate the air cushion to maintain the substrate 140 in the upright position. Thus, the pressure generated by the injected gas material maintains the substrate 140 at a distance apart from the cathode 132. Hence, the substrate 140 can be transferred while being fixed to a roller (not shown).

In another embodiment, a carrier (not shown) is used to maintain the substrate 140 being transferred in the upright position in the in-line sputtering apparatus. The substrate 140 may be attached to the carrier. A bottom surface of the carrier may be connected with a metal belt. Then, the carrier and the substrate 140 attached thereto are transferred from a position to the next by the motion of the metal belt.

A target 131 is attached to the front surface of the cathode 132. In an embodiment as shown in FIG. 3, the target 131 may have an integral structure. In another embodiment, the target 131 may be segmented into a plurality of pieces, and these pieces are attached individually to the cathode 132 spaced apart from each other.

A voltage is applied to the cathode 132 to ionize a gas in the sputtering chamber 124. Hence, a gaseous plasma is generated in the sputtering apparatus in a plasma region 210 in front of the cathode 132. Positive ions in the gaseous plasma collide with the target 131 to cause a target material to be discharged from the target 131. The target material is deposited over the substrate 140.

A first magnet is placed on a top portion of the carrier and a second magnet is arranged to face the first magnet to retain the substrate 140 in a fixed position. The second magnet has an opposite polarity to the first magnet. Hence, when the substrate 140 is transferred into the sputtering apparatus, the substrate 140 is kept in its upright position apart from the cathode 132 by an attraction force between the first magnet and the second magnet.

A plurality of magnets 236a, 236b and 236c are arranged spaced apart from each other at the back of the cathode 132. The magnets 236a, 236b and 236c are arranged to face respective corresponding pieces of the target 131. Thus, the density of a plasma existing over the front surface of the individual pieces of the target 131 may be controlled. In another embodiment, the position of the magnets 236a, 236b and 236c may not correspond to the respective pieces of the target 131.

A plurality of jigs 235a, 235b and 235c hold the respective magnets 236a, 236b and 236c. The jigs 235a, 235b and 235c are connected with respective driving motors 230a, 230b and 230c through respective guide members 233a, 233b and 233c. The guide member 233a is placed between the driving motor 230a and the jig 235a; the guide member 233b is placed between the driving motor 230b and the jig 235b; and the guide member 233c is placed between the driving motor 230c and the jig 235c. The guide members 233a, 233b and 233c are moved in a direction substantially perpendicular to the cathode 132 by the respective driving motors 230a, 230b and 230c. Hence, the magnets 236a, 236b and 236c connected to the respective driving motors 230a, 230b and 230c may move close to or away from the cathode 132 due to the respective driving motors 230a, 230b and 230c.

Each of the magnets 236a, 236b and 236c may also move in a direction substantially parallel to the cathode 132. In an embodiment, the driving motors 230a, 230b and 230c may be operated to move in a direction substantially parallel to the respective guide members 233a, 233b and 233c. In another embodiment, additional motors may be provided to move the respective guide members 233a, 233b and 233c in parallel to the cathode 132.

In an embodiment, each of the magnets 236a, 236b and 236c may have a magnetic field with a fixed intensity. For example, each of the magnets 236a, 236b and 236c may have a magnetic field intensity of approximately 900 G for depositing a metal-based material on the substrate 140.

In accordance with an embodiment, the sputtering apparatus may deposit a metal-based material on the substrate 140. The intensity of a magnetic field in a plasma region 210 may be controlled by the motion of each of the magnets 236a, 236b and 236c in a direction substantially perpendicular to the cathode 132. For example, the intensity of the magnetic field exerted over the plasma region 210 can be changed by moving the magnets 236a, 236b and 236c closer to or away from, and in the direction perpendicular to the plasma region 210 formed at a front of the cathode 132.

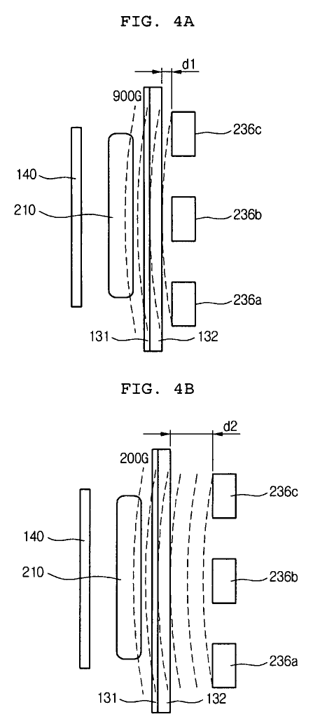

FIGS. 4A and 4B are schematic diagrams illustrating exemplary control of the magnetic field intensity in the in-line sputtering apparatus illustrated in FIG. 3. Referring to FIG. 4A, the cathode 132 is spaced apart from each of the magnets 236a, 236b and 236c by a first distance dl to preset the magnetic field intensity of each of the magnets 236a, 236b and 236c to about 900 G in the plasma region 210. Then, a metal-based material is deposited on the substrate 140 by subjecting the target 131 with the metal-based material attached thereto to the above preset magnetic field intensity of about 900 G. Thus, the spacing distance d1 between the cathode 132 and each of the magnets 236a, 236b and 236c can be chosen appropriately for exerting a magnetic field intensity of about 900 G over the plasma region 210 and depositing the metal-based material on the substrate.

Referring to FIG. 4B, the cathode 132 is spaced apart from each of the magnets 236a, 236b and 236c by a second distance d2 larger than dl to preset the magnetic field intensity of each of the magnets 236a, 236b and 236c to about 200 G in the plasma region 210. By increasing the spacing distance between the cathode 132 and each of the magnets 236a, 236b and 236c from d1 to d2, other materials can be deposited. For example, the larger spacing distance d2 can be selected for depositing an ITO-based material using the sputtering apparatus of FIG. 3. As described above, a magnetic field intensity of approximately 200 G in the plasma region 210 is appropriate for depositing the ITO-based material on the substrate 140.

As illustrated in FIG. 4B, the target 131 includes an ITO-based material attached thereto. Then, the ITO material is deposited on the substrate 140 by subjecting the target 131 with the ITO-based material attached thereto to the above preset magnetic field intensity of about 200 G. Thus, each of the magnets 236a, 236b and 236c is moved in a direction perpendicular to the cathode 132 to vary the magnetic field intensity in the plasma region 210. To decrease the intensity of the magnetic field in the plasma region 210 from about 900 G to about 200 G, the magnets 236a, 236b and 236c are moved away from the cathode 132 to the second distance d2. The spacing distance d2 for generating a magnetic field intensity of about 200 G in the plasma region 210 is larger than the spacing distance dl for generating a magnetic field intensity of about 900 G in the plasma region 210.

In an embodiment of the present invention, The cathode 132 and each of the magnets 236a, 236b and 236c satisfy the following magnetic field-distance relationship. The magnetic field intensity is inversely proportional to the distance between the cathode 132 and each of the magnets 236a, 236b and 236c. For example, the magnetic field intensity generated in the plasma region 210 increases when the distance between the cathode 132 and each of the magnets 236a, 236b and 236c decreases. In contrast, the magnetic field intensity in the plasma region 210 decreases as the distance between the cathode 132 and each of the magnets 236a, 236b and 236c increases.

In accordance with an embodiment of the present invention, the intensity of the magnetic field in the plasma region 210 is controlled by adjusting the distance between the cathode 132 and each of the magnets 236a, 236b and 236c in accordance with the above-described magnetic field-distance relationship. Hence, different types of materials may be deposited using the same in-line sputtering apparatus. Accordingly, the functionality of the in-line sputtering apparatus may be improved. Moreover, purchasing costs may be reduced because a since the single in-line sputtering apparatus may be used for different material deposition processes. Furthermore, the installation area for the in-line sputtering apparatus may be reduced because a single in-line sputtering apparatus can be installed.

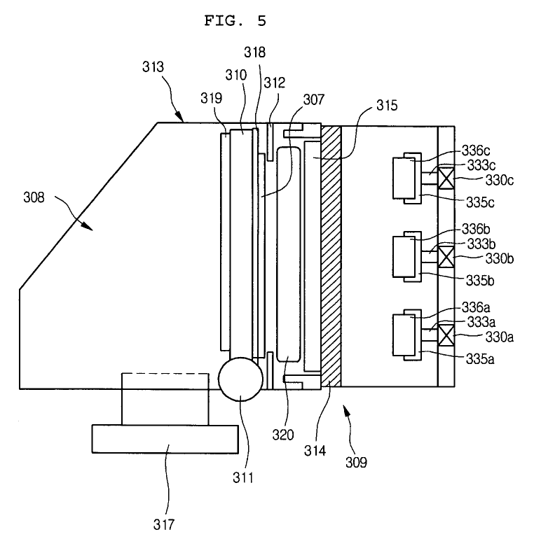

FIG. 5 is a cross-sectional view of an exemplary cluster type sputtering apparatus according to an embodiment of the present invention. Referring to FIG. 5, the cluster type sputtering apparatus includes a substrate maintaining block 308 and a sputtering block 309. The substrate maintaining block 308 holds a substrate 307, and the sputtering block 309 sputters the substrate 307. A vacuum pump 317 is provided for exhausting air to drive the cluster type sputtering apparatus to a vacuum state.

The substrate maintaining block 308 includes a substrate maintaining plate 310 and a shaft 311 connected with the substrate maintaining plate 310. The shaft 311 rotates the substrate maintaining plate 310 in a vertical or horizontal direction. A susceptor 318 is installed over the substrate maintaining plate 310 to hold the substrate 307 against the susceptor 318. A sheath heater 319 is installed over the bottom surface of the substrate maintaining plate 310 to maintain the substrate 307 at a consistent temperature. The sheath heater 319, the substrate maintaining plate 310 and the susceptor 318 contact each other. Thus, heat is transferred from the sheath heater 319 to the substrate 307 through the substrate maintaining plate 310 and the susceptor 318. The transferred heat provides a consistent thickness for a layer of material deposited over the substrate 307.

The sputtering block 309 includes a cathode 314, a target 315, a plurality of magnets 336a, 336b and 336c, a plurality of guide members 333a, 333b and 333c, a plurality of driving motors 330a, 330b and 330c, and a plurality of jigs 335a, 335b and 335c. A voltage is applied to the cathode 314. The target 315 is attached to the front surface of the cathode 314 and discharges a target material due to positive ions from a gaseous plasma. Each of the magnets 336a, 336b and 336c is arranged at the back of the cathode 314 to be spaced apart from the cathode 314 and generate a large amount of positive ions around the target 315. The guide members 333a, 333b and 333c are connected to the respective magnets 336a, 336b and 336c such that each of the magnets 336a, 336b and 336c may move in a direction perpendicular to the cathode 314. The respective guide members 333a, 333b and 333c are moved by the driving motors 330a, 330b and 330c. The jigs 335a, 335b and 335c are connected to the respective guide members 333a, 333b and 333c to hold the respective magnets 336a, 336b and 336c.

In an embodiment as shown in FIG. 5, the target 315 may have an integral structure. In another embodiment, the target 315 may be segmented into a plurality of pieces, and these pieces are attached individually to the cathode 314 spaced apart from each other.

Each of the guide members 333a, 333b and 333c is moved in a direction perpendicular to the cathode 314 by the driving motors 330a, 330b and 330c. Moreover, each of the magnets 336a, 336b and 336c may also move in a direction parallel to the cathode 314. Each of the magnets 336a, 336b and 336c is set to have a specified magnetic field intensity.

The substrate maintaining plate 310 rotates either vertically or horizontally due to the shaft 311. That is, when the substrate 307 is carried inside the sputtering apparatus, the substrate maintaining plate 310 holds the substrate 307 in a horizontal direction. As a result, the substrate 307 is held against the substrate maintaining plate 310. The substrate 307 may be held by a clamp (not shown) provided on the substrate maintaining plate 310 to prevent the substrate 307 from moving. The shaft 311 rotates vertically to bring the substrate maintaining plate 310 in face of a shield mask 312. The shield mask 312 is formed on the inner surface of a body 313 of the sputtering apparatus to separate the substrate maintaining block 308 and the sputtering block 309 from each other. The shield mask 312 masks regions other than the substrate 307.

A gaseous plasma is generated in a plasma region 320 by applying a voltage to the cathode 314. Positive ions generated by the gaseous plasma collide with the target 315 and cause a target material to be discharged from the target 315. The discharged target material is deposited over the substrate 307. Another magnet may be provided to generate a magnetic field around the target 315 to increase the density of the gaseous plasma, and thus, increase the amount of the discharged target material in a given time period. Accordingly, a deposition time of the target material on the substrate 307 may be shortened. Once the discharged target material is deposited on the substrate 307, the shaft 311 rotates the substrate maintaining plate 310 in a horizontal direction, and the substrate 307 is transferred and the clamp is removed to release the substrate 307.

The jigs 335a, 335b and 335c connected to the respective magnets 336a, 336b and 336c holds the respective magnets 336a,336b and 336c. The jigs 335a,335b and 335c are also connected with the respective guide members 333a, 333b and 333c, and thus, the respective magnets 336a, 336b and 336c may move with the respective guide members 333a, 333b and 333c. The guide members 333a, 333b and 333c are connected with the respective driving motors 330a, 330b and 330c provided in the body 313 of the sputtering apparatus. Thus, the respective guide members 333a, 333b and 333c move with the driving motors 330a, 330b and 330c in a direction perpendicular to the cathode 314 s.

For example, the target 315 including a metal-based material is attached to the cathode 314 to deposit the metal-based material. Each of the guide members 333a, 333b and 333c is moved toward the cathode 314 to increase the magnetic field intensity to about 900 G in the plasma region 320 for depositing the metal-based material. As a result, each of the magnets 336a, 336b and 336c moves closer to the cathode 314 than their original position. Hence, the magnetic field intensity in the plasma region 320 increases. The guide members 333a, 333b and 333c are stopped when the magnetic field intensity in the plasma region 320 reaches approximately 900 G.

In another example, the target 315 including an ITO-based material is attached to the cathode 314 to deposit the ITO-based material. Each of the guide members 333a, 333b and 333c is moved away from the cathode 314 to reduce the magnetic field intensity to about 200 G in the plasma region 320. By moving each of the magnets 336a, 336b and 336c away from the cathode 314, the magnetic field intensity in the plasma region 320 decreases. The guide members 333a, 333b and 333c are stopped when the magnetic field intensity in the plasma region 320 reaches about 200 G.

In accordance with an embodiment of the present invention, the intensity of the magnetic field in the plasma region 320 is controlled by adjusting a distance between the cathode 314 and each of the magnets 336a, 336b and 336c. The distance adjustment may be achieved by moving the individual magnets 336a, 336b and 336c. By controlling of the magnetic field intensity, different materials can be deposited using a single cluster type sputtering apparatus. Hence, the cluster type sputtering apparatus may be used in more various fields than the related art sputtering apparatus. Moreover, the functionality of the cluster type sputtering apparatus may be improved. Furthermore, since many different cluster type sputtering apparatuses are not required for depositing different materials, the purchase costs and an installation area of the sputtering apparatus may be reduced.

In accordance with an embodiment of the present invention, the intensity of the magnetic field in a plasma region is controlled by moving magnets having a fixed magnetic field intensity of an in-line sputtering apparatus. Hence, a single in-line sputtering apparatus may be used to deposit many different materials, thus increasing the usefulness of the in-line sputtering apparatus. The functionality of the in-line sputtering apparatus can also increase. Moreover, cost-effectiveness may be improved due to the reduction in purchasing cost and installation area of the in-line sputtering apparatus.

Moreover, in accordance with an embodiment of the present invention, the intensity of the magnetic field in a plasma region is controlled by moving magnets having a fixed magnetic field intensity of a cluster type sputtering apparatus. Hence, a single cluster type sputtering apparatus may be used to deposit many different materials, thus increasing the usefulness of the cluster type sputtering apparatus. The functionality of the cluster type sputtering apparatus can also increase. Moreover, cost-effectiveness may be improved due to the reduction in purchasing cost and installation area of the cluster type sputtering apparatus.

Furthermore, in accordance with an embodiment of the present invention, the intensity of the magnetic field in a plasma region is controlled by moving magnets having a fixed magnetic field intensity. Hence, a single sputtering apparatus may be used to deposit many different materials, thus increasing the usefulness of the sputtering apparatus. The functionality of the sputtering apparatus can also increase. Moreover, cost-effectiveness may be improved due to the reduction in purchasing cost and installation area of the sputtering apparatus.

It will be apparent to those skilled in the art that various modifications and variations can be made in the sputtering apparatus of embodiments of the present invention. Thus, it is intended that embodiments of the present invention cover the modifications and variations of the embodiments described herein provided they come within the scope of the appended claims and their equivalents.

What is claimed is:

1. A sputtering apparatus, comprising:
a cathode for generating a plasma;
one or more target on a front surface of the cathode;
a plurality of magnets at a first distance from a back of the cathode for generating a first magnetic field intensity in the plasma; and
a plurality of guide members for moving the individual magnets in a direction substantially perpendicular to the cathode to a second distance from the back of the cathode to change the first magnetic field intensity to a second magnetic field intensity.

2. The sputtering apparatus of claim 1, wherein the first magnetic field intensity is appropriate for depositing a metal on a substrate in the plasma region.

3. The sputtering apparatus of claim 1, wherein the first magnetic field intensity is larger than the second magnetic field intensity.

4. The sputtering apparatus of claim 1, wherein the first magnetic field intensity is lower than the second magnetic field intensity.

5. The sputtering apparatus of claim 1, wherein the second magnetic field intensity is appropriate for depositing an ITO material on a substrate in the plasma region.

6. The sputtering apparatus of claim 1, wherein the first and second magnetic field intensities are appropriate for respectively depositing first and second materials on a substrate in the plasma region.

7. The sputtering apparatus according to claim 1, further comprising:
a plurality of jigs holding the respective magnets and connected with the respective guide members; and
a plurality of motors for moving the respective guide members and the magnets in the direction substantially perpendicular to the cathode.

8. The sputtering apparatus according to claim 1, wherein each of the plurality of the motors is attached to a body of the sputtering apparatus.

9. The sputtering apparatus according to claim 1, further comprising a heater for heating a substrate between the target and the heater.

10. The sputtering apparatus according to claim 1, wherein the plurality of magnets move in a direction substantially parallel to the cathode.

11. The sputtering apparatus according to claim 1, wherein the plurality of magnets move in a direction substantially perpendicular to the cathode.

12. An LCD device fabricated in the sputtering apparatus of claim 9.

13. An LCD device fabricated in the sputtering apparatus of claim 1.

14. A sputtering apparatus comprising:
a maintaining part for holding a substrate; and a sputtering part, comprising
a cathode for generating a plasma;
one or more target on a front surface of the cathode;
a plurality of magnets at a first distance from a back of the cathode for generating a first magnetic field intensity in the plasma; and
a plurality of guide members for moving the individual magnets in a direction substantially perpendicular to the cathode to a second distance from the back of the cathode to change the first magnetic field intensity to a second magnetic field intensity.

15. The sputtering apparatus of claim 14, wherein the first magnetic field intensity is appropriate for depositing a metal on the substrate.

16. The sputtering apparatus of claim 14, wherein the first magnetic field intensity is larger than the second magnetic field intensity.

17. The sputtering apparatus of claim 14, wherein the first magnetic field intensity is lower than the second magnetic field intensity.

18. The sputtering apparatus of claim 14, wherein the second magnetic field intensity is appropriate for depositing an ITO material on the substrate.

19. The sputtering apparatus according to claim 14, further comprising:
a plurality of jigs holding the respective magnets and connected with the respective guide members; and
a plurality of motors for moving the respective guide members and the magnets in the direction substantially perpendicular to the cathode.

20. The sputtering apparatus according to claim 14, wherein each of the plurality of the motors is attached to a body of the sputtering apparatus.

21. The sputtering apparatus according to claim 14, further comprising a heater for heating the substrate.

22. The sputtering apparatus of claim 14, further comprising:
a plate for holding the substrate to the maintaining part; and
a shaft for rotating the plate and the substrate held therewith in a vertical or a horizontal direction.

23. An LCD device fabricated in the sputtering apparatus of claim 20.

24. An LCD device fabricated in the sputtering apparatus of claim 14.

25. An operating method of a sputtering apparatus, comprising:
proving a substrate in a plasma region;
generating a plasma using a cathode; and
moving a plurality of magnets in a direction perpendicular to the cathode to control a magnet field intensity in the plasma region.

26. The operating method according to claim 25, wherein the plurality of magnets are stopped moving when the magnetic field intensity is appropriate for depositing a material on a substrate in the plasma region.

27. The operating method according to claim 25, wherein the material is one of metal and ITO material.
